(19) United States
(12) Patent Application Publication
(10) Pub. No.: US 2013/0171819 A1
(43) Pub. Date: Jul. 4, 2013

(54) METHODS FOR INTEGRATION OF METAL/DIELECTRIC INTERCONNECTS

(71) Applicants: Hideshi Miyajima, Clifton Park, NY (US); Hideaki Masuda, White Plains, NY (US)

(72) Inventors: Hideshi Miyajima, Clifton Park, NY (US); Hideaki Masuda, White Plains, NY (US)

(73) Assignee: TOSHIBA AMERICA ELECTRONIC COMPONENTS, INC., Irvine, CA (US)

(21) Appl. No.: 13/338,486

(22) Filed: Dec. 28, 2011

(51) Int. Cl. H01L 21/768

(52) U.S. Cl. 438/667; 257/E21.585

(57) ABSTRACT

Described herein are methods for copper/low-k dielectric material integration. The methods involve depositing and curing a low-k dielectric material and depositing a mask on the low-k dielectric material. A via is patterned in the low-k dielectric material and a trench is patterned in the low-k dielectric material. After the via or trench is patterned, a portion of the low-k material is backfilled with a backfill material. The trench and via are filled with copper, then the mask and the copper filling the via are removed. After a first pre-CLN, the backfill material is removed. This creates a robust copper/porous low-k dielectric material interconnect.

### FIELD

Embodiments described herein generally relate to methods for integration of metal/dielectric interconnects.

### BACKGROUND

Back end of line (BEOL) denotes the second portion of integrated circuit (IC) fabrication, in which metal layers are interconnected by an interconnect metal with a dielectric material disposed around it. Historically, interconnects have been made using aluminum/silicon dioxide; however, as the number of interconnect levels for logic has increased, timing delay due to the resistance of the metal and the parasitic capacitance of the dielectric has become a serious problem.

To counteract this problem, copper/porous low-k dielectric material have replaced aluminum/silicon dioxide as interconnect materials. Using copper as the interconnect metal can reduce the resistance, while the porous low-k dielectric material can lower the parasitic capacitance. However, the porous low-k dielectric material is susceptible to plasma damage, which can not only degrade the k-value, but also decrease the reliability of the copper. Increasing the carbon content in the low-k dielectric material is known to improve resistance to plasma damage, but carbon also decreases the mechanical strength of the material.

### BRIEF DESCRIPTION OF DRAWINGS

FIG. 1 shows a schematic process flow diagram of a method employing pore backfilling for creating a robust copper/porous low-k interconnect.

FIG. 2 shows a schematic diagram of plasma damage caused by a porous low-k dielectric during dual damascene processing.

FIG. 3 shows a schematic diagram of a method employing pore backfilling to reduce the plasma damage during dual damascene processing.

FIG. 4 shows a schematic diagram of porous low-k semiconductor material with various levels of backfilling.

FIG. 5 shows scanning electron microscope (SEM) images of the surface of porous low-k semiconductor materials after backfilling.

FIG. 6 shows plots corresponding to the SEM images of FIG. 5.

FIG. 7 shows a schematic diagram of a convention dual damascene process.

FIG. 8 shows a schematic diagram of a simple pore backfilling dual damascene process.

FIG. 9 shows a schematic diagram of a problem inherent with the simple pore backfilling dual damascene process.

FIG. 10 shows a schematic diagram of a problem inherent with the simple pore backfilling dual damascene process.

FIG. 11 shows a schematic diagram of a problem inherent with the simple pore backfilling dual damascene process.

FIG. 12 shows a schematic diagram of an alternate pore backfilling dual damascene process.

FIG. 13 shows a schematic diagram of an alternate pore backfilling dual damascene process.

FIG. 14 shows a schematic diagram of an alternate pore backfilling dual damascene process.

FIG. 15 shows a schematic diagram of an alternate pore backfilling dual damascene process.

FIG. 16 shows a schematic diagram of an alternate poor back filling dual damascene process.

### DETAILED DESCRIPTION

According to one or more aspects, the subject innovation generally relates to methods for achieving robust metal/dielectric interconnects for high performance logic devices and devices manufactured according to these methods. The interconnects described herein utilize copper metal and porous low-k dielectric materials. However, any metal that exhibits a better conductivity than aluminum and any dielectric material with a dielectric constant lower than silicon dioxide can be similarly utilized to create the robust metal/dielectric interconnects described herein.

These methods involve backfilling the dielectric material with a carbon containing material to create a dielectric material that is more resistant to damage due to subsequent integration before integration and subsequently, after integration, removing the carbon containing material from the dielectric material. When the carbon containing material is removed, the dielectric material can again exhibit favorable properties of the softer dielectric material, such as a lower k value, without damage due to integration.

In the case of porous low-k dielectric material, the carbon can fill the pores of the porous low-k material to create a carbon-doped low-k material and then the carbon material can be removed from the pores, again creating the porous low-k material. The porous low-k material can include pores that are at least partially connected. To easily refill pores in a low-k film, connected pores are helpful.

The backfilling can occur after the porous low-k material is formed, creating a high carbon doped material without pores, which can be effective in removing plasma damage. Then, after copper dual damascene integration, the hydrocarbon material can be completely removed from the pores, creating a robust copper/porous low-k dielectric material interconnect.

According to an embodiment, the backfilling can occur between via mask patterning and via patterning. Pores around the via hole pattern region can be backfilled, while other pores located remotely from the via hole pattern can be left unfilled.

According to another embodiment, the backfilling can occur between trench mask patterning and trench patterning. Pores around the trench pattern region can be backfilled, while other pores located remotely from the trench can be left unfilled.

The subject innovation is now described with reference to the drawings, wherein like reference numerals are used to refer to like elements throughout. In the following description, for purposes of explanation, numerous specific details are set forth in order to provide a thorough understanding of the subject innovation. It may be evident, however, that the subject innovation may be practiced without these specific details. In other instances, well-known structures and devices are shown in block diagram form in order to facilitate describing the subject innovation.

With respect to any figure or numerical range for a given characteristic, a figure or a parameter from one range may be combined with another figure or a parameter from a different range for the same characteristic to generate a numerical range.

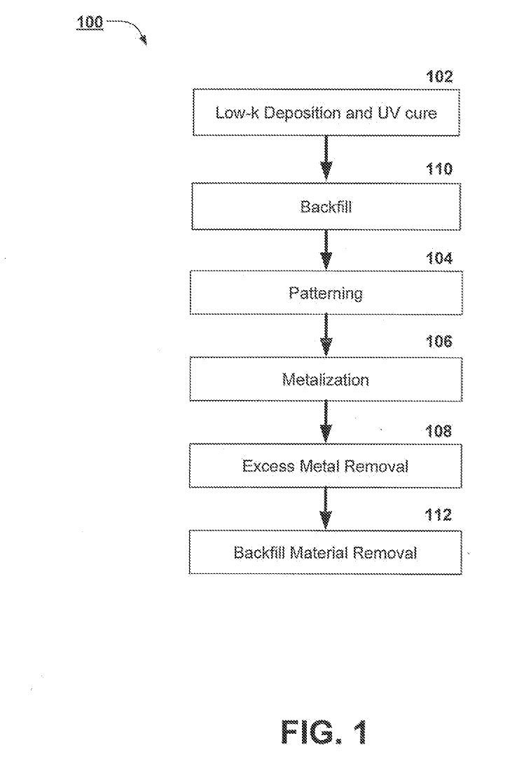

Referring now to FIG. 1, shows a schematic process flow diagram of a method 100 employed during back end of line (BEOL) processing for the creation of metal interconnecting wires that are isolated by dielectric layers (“interconnects”) between various semiconductor devices on a chip.

Historically, the interconnects were made of aluminum and silicon dioxide. With the development of high performance logic devices, however, aluminum and silicon dioxide have become impractical. As the number of interconnect levels for logic has increased, timing delay due to the resistance (R) of the aluminum metal and the parasitic capacitance (C) of the silicon dioxide dielectric has become a serious problem. As compartments have scaled down and transistors have gotten closer together, the interconnects have gotten smaller and the dielectrics have thinned to the point where charge build up and cross talk can adversely affect the performance of the device. High performance logic devices with these small compartments and scaled down transistors require elimination of the RC time delay inherent with aluminum and silicon dioxide.

To reduce this timing delay, high performance logic devices with circuit elements located closer together require smaller BEOL interconnects that necessitate a metal that exhibits a lower resistance than aluminum and a dielectric that exhibits a lower parasitic capacitance than silicon dioxide. Copper is a better conductor than aluminum that exhibits a lower resistance than aluminum. A dielectric material that exhibits a lower parasitic capacitance than silicon dioxide is a low-k dielectric material, which, by definition, has a small dielectric constant relative to silicon dioxide. The smaller dielectric constant enables a low-k dielectric of the same thickness to exhibit a reduced parasitic capacitance than silicon dioxide. The dielectric material can be a low-k dielectric material that includes silicon, carbon, oxygen and hydrogen and can include pores.

The dielectric constant of a material is the ratio of the permittivity of the material and the permittivity of a vacuum. The dielectric constant of silicon dioxide is from about 3.9 to about 4.2. Examples of low-k materials include fluorine-doped silicon dioxide, which has a k value from about 3.9 to about 3.7, carbon-doped silicon dioxide, which has a k value of about 3.7, porous silicon dioxide, which has a k value of about 2.0, and porous carbon-doped silicon dioxide, which has a k value from about 2.5 to about 2.0.

Currently, the method for creating interconnects includes deposition of a low-k dielectric material (through spin coating or any other deposition method) and curing (UV curing or any other curing method) the low-k material 102. UV curing can facilitate the integration of pores into the low-k dielectric material. After the UV curing, the low-k material can be porous silicon dioxide, which exhibits a low k value, which reduces the parasitic capacitance. However, porous silicon dioxide, including silicon, carbon, oxygen and hydrogen, also has a low mechanical strength, which can lead to packaging issues. The porous silicon dioxide also has low plasma-induced damage (PID) resistance. After deposition and curing, the low-k material undergoes patterning 104, which can cause PID damage, which can lead to capacitance increase and moisture absorption. Including carbon to create a porous carbon-doped silicon dioxide can increase PID resistance, but can decrease mechanical strength and increase the k value, which can lead to increased parasitic capacitance.

The patterning 104 can be a dual damascene process, which is used to create multi-level high density metal interconnects needed for advanced, high performance logic devices. The dual damascene process is a process that includes patterning 104, metallization 106, and removal of excess metal 108.

Because copper does not form a volatile by-product, it is often very difficult to etch. Therefore, copper metallization schemes cannot be realized using the traditional subtractive etching approached used to form aluminum interconnects. The dual damascene technique overcomes this problem by etching a columnar via hole, followed by a trench etch into the low-k material (patterning 104), and then filling both the via and trench structures with copper (metallization 106), which is subsequently polished back using chemical mechanical polishing (CMP) to the surface of low-k material (removal of excess metal 108).

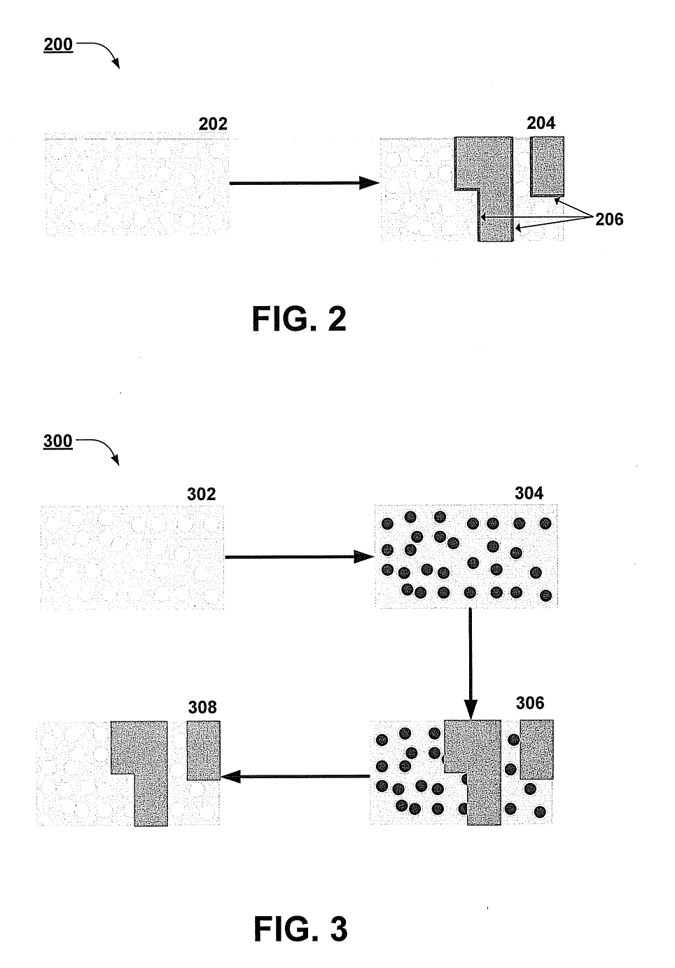

When porous silicon dioxide is used as the low-k dielectric, it exhibits integration difficulties, such as low mechanical strength and difficult integration with etch and polish processes. This can be shown schematically in FIG. 2. A porous low-k material that is deposited and cured 102 can undergo dual damascene processing 204 to create copper interconnects, but the porous low-k material it suffers from PID damage 206 around the copper metal deposited during dual damascene processing.

Carbon-doped silicon dioxide can increase the mechanical strength, thereby facilitating the integration with the etch and polish processes. This can be shown schematically in FIG. 3. The porous low-k material that is deposited and cured 302 can undergo backfilling with a hydrocarbon material to reduce the number of pores 304. The dual damascene processing can occur on the backfilled low-k material, allowing copper metal to be deposited during dual damascene processing without causing PID damage 306. However, carbon-doped silicon dioxide has a higher k-value than porous silicon dioxide, so it is preferred for the interconnect to have a porous silicon dioxide interconnect with a lower k value than a carbon-doped silicon dioxide interconnect. Accordingly, the backfill hydrocarbon material can be removed from the dielectric so that the dielectric is a porous low-k material again, creating a robust copper/porous low-k material interconnect 308.

Carbon is needed during the dual damascene steps of method 100 (the “plasma process”) to fill the pores of the porous low-k material, where the etching and polishing can damage the porous low-k dielectric due to inherent low mechanical strength, but is unnecessary thereafter. Accordingly, after the low-k deposition and UV cure 102 and before the patterning 104, an additional step can be added to method 100 that involves backfilling 110 or refilling the low-k material with a carbon-containing material, such as a hydrocarbon. This allows a high amount of carbon to fill the pores during dual damascene steps, such as patterning 104, metallization 106, and excess metal removal. The backfill material can be removed 112 so that the final interconnect has a porous low-k material as a dielectric. With backfill 110 and backfill material removal 112, which can create a stronger dielectric material during dual damascene processing steps, method 100 can create a robust copper/porous low-k interconnect.

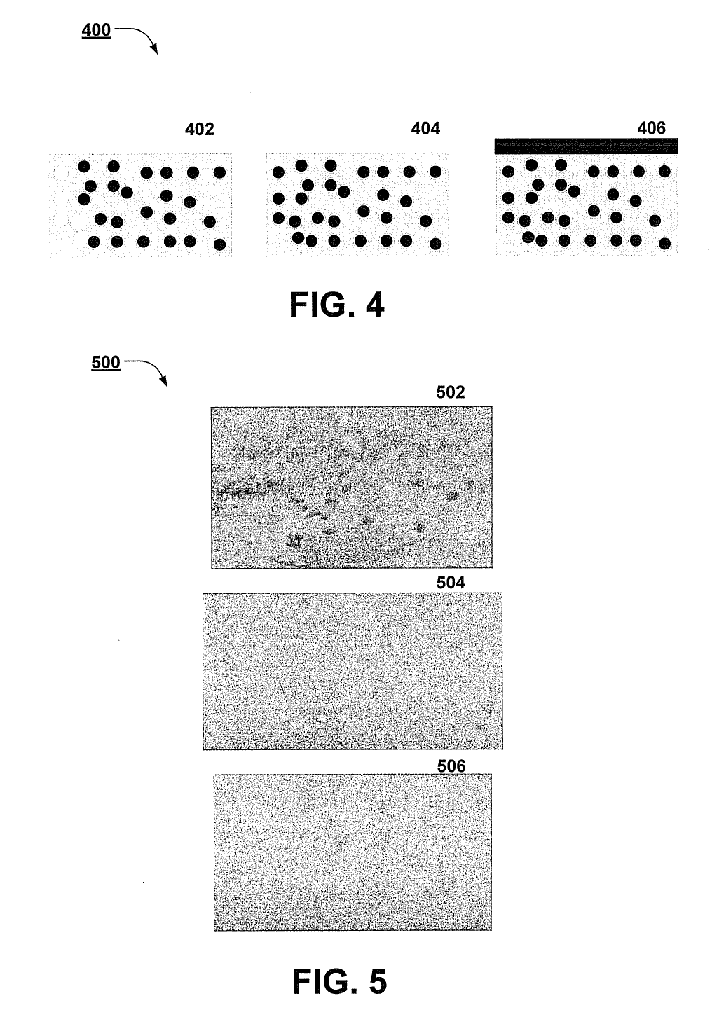

The backfill 110 can be accomplished through spin coating. Other methods of applying the backfill material can be employed, like simply dipping in solution, but spin coating is described herein for simplicity of explanation. As shown in FIG. 4, different amounts of backfill material can fill the pores of the porous low-k material based on parameters of the spin coating, such as the concentration of the backfill material in the solution placed on the porous low-k dielectric, the rotation speed, the time of rotation, and the like.

The backfill material can fill the porous low-k material so the pores are not all filled 402, the pores are completely filled 404, the pores are completely filled and additional areas (like the outside of the low-k material) are filled 406, or any amount in between, based on parameters of the spin coating process. In the process shown in FIG. 1, perfect refilling 404 is necessary to can create a dielectric without pores that can exhibit high mechanical strength during dual damascene processing that minimizes the

PID damage, while facilitating removal of the backfill material after the dual damascene processing. However, less than perfect refilling 402 can also be useful for other methods for creating robust metal/dielectric interconnects by employing dual damascene processing.

The backfill material can be a resin, such as an acrylic-type resin, a polystyrene-type resin, or any other hydrocarbon based resin. The hydrocarbon based resin can have the characteristic of thermal stability at temperatures less than a temperature (T₀) and thermal decomposition at greater than the temperature (T₀). According to an embodiment, T₀ can be from about 100 degrees C. to about 500 degrees C. According to another embodiment, T₀ can be from about 150 degrees C. to about 450 degrees Celsius (C). In a further embodiment, T₀ can be from about 200 degrees C. to, about 400 degrees C.

This property of thermal stability enables the backfill material to be removed 112 through a thermal treatment. The thermal treatment can be performed at a temperature less than about 450 degrees C. The removal 112 can also employ a wet treatment, an ultra violet treatment, an electron beam treatment, or any other treatment that can facilitate an efficient removal of the backfill material without damaging the low-k dielectric.

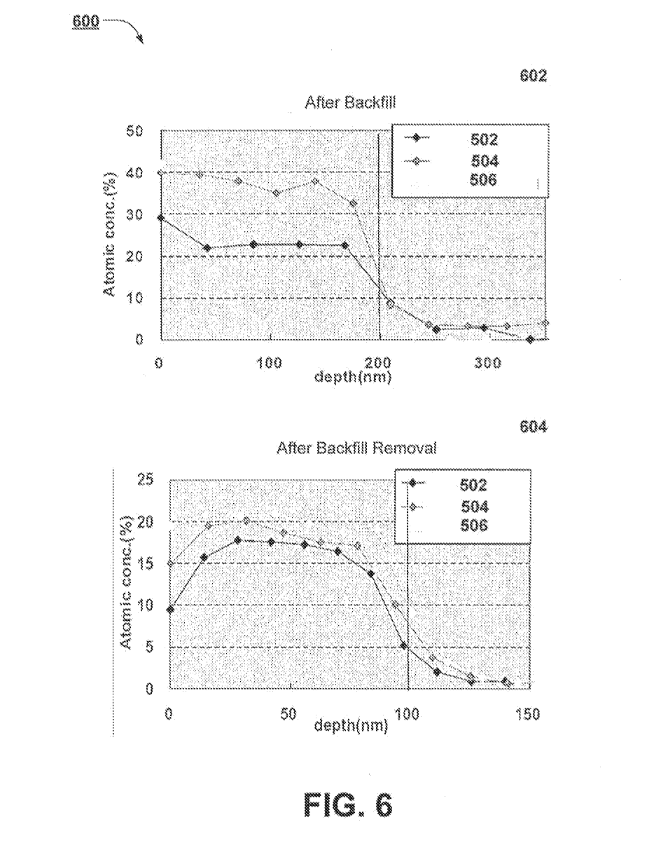

The removal process can create a porous dielectric similar to a porous dielectric that did not undergo backfill and subsequent removal. The surface affects of backfill and subsequent removal are shown in FIGS. 5 and 6. FIG. 5 shows scanning electron microscopy (SEM) images 500 of the surface of three low-k materials: a control (that has not undergone backfill addition and removal) 502 and two low-k dielectric materials that have undergone backfill addition and removal 504, 506. Different backfill materials was used for 504 and 506.

FIG. 6 shows plots 600 illustrating properties of the surfaces shown in FIG. 5. Elements 602 and 604 show a carbon depth profile by XPS analysis. Element 604 is an XPS comparison between the conventional approach (after half etch 200 nm to 100 nm) and the approach described herein after half etch and backfill material removal.

As shown in 604, the SEM image 502 of the control material that has undergone the conventional approach shows the largest surface damage and carbon content degradation in the all bulk region. The material that has undergone the approach described herein 504 shows lower surface damage, and 502 shows no damage. This study confirmed the effectiveness of the backfilling approach described herein.

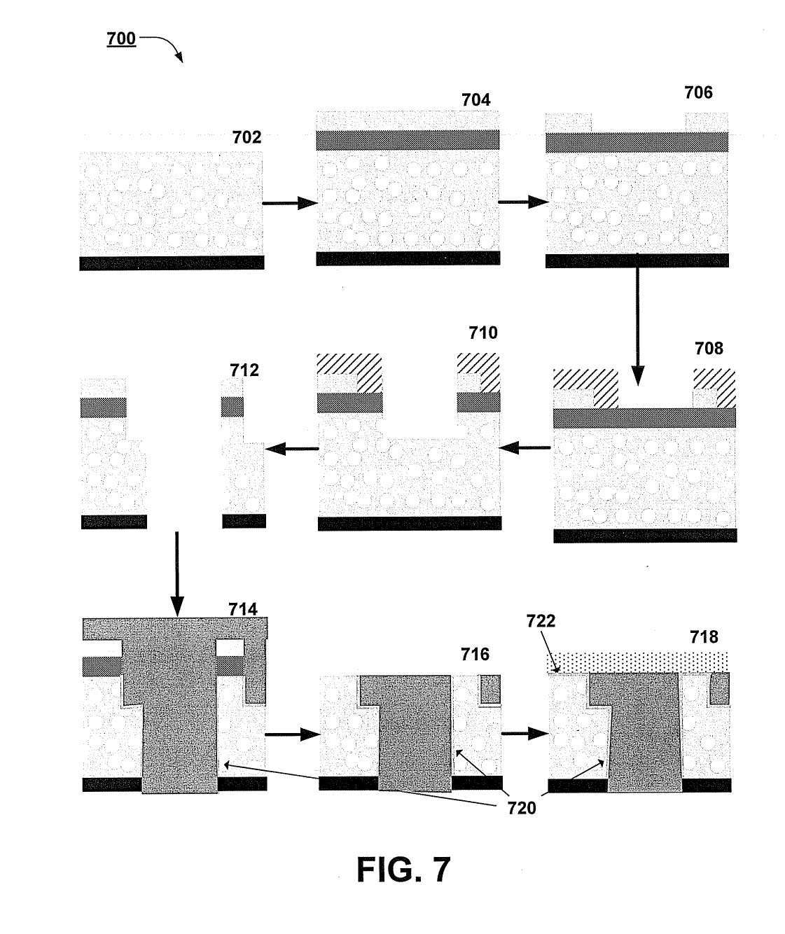

A more detailed illustration of a conventional dual damascene process 700 is illustrated in FIG. 7. Although a via-first sequence is described, a trench-first sequence any other sequence utilized in dual damascene processing can be applied in a similar way.

As described above, a porous low-k material is deposited and cured 702, hard mask (HM) layers are deposited on the surface of the porous low-k material 704. The HM layers include an oxide HM on the surface of the porous low-k material and a metal HM on the surface of the oxide HM. The metal HM is opened 706 and a via mask is applied 708. Using the via mask as a guide, a via is defined through etching 710 through the HM layers and into the low-k dielectric material.

Although not illustrated, it will be understood that via etching includes three steps. For the first etch, as shown at 710, the via mask is used as masking and the via etch is stopped short. During the next trench oxide hard mask etch, vias are slightly etched (second via etch, not shown). At the next trench etch step, the metal HM is used as masking and simultaneously the via etch is complete (third via etch) 712.

The via mask is removed, and a trench is etched through the HM layers and the low-k dielectric 712. The via and trench are then simultaneously filled, creating a copper-filled trench and via 714. The HM layers and excess copper are removed through polishing (CMP, for example) 716, creating a copper/low-k interconnect. Then the interconnect undergoes additional cleaning (pre-CLN with NH₃ plasma) to remove oxides from the copper and subsequent cap deposition 718.

The low-k semiconductor material exhibits PID damage 720 due to the addition of the copper. The low-k material also exhibits additional surface damage 722 caused by the pre-CLN with NH₃ plasma. Due to the PID damage 720 and surface damage 722, the low-k material can exhibit hygroscopy (allowing the material to attract water and become physically changed) and an increase in k. The copper can also become degraded and less reliable.

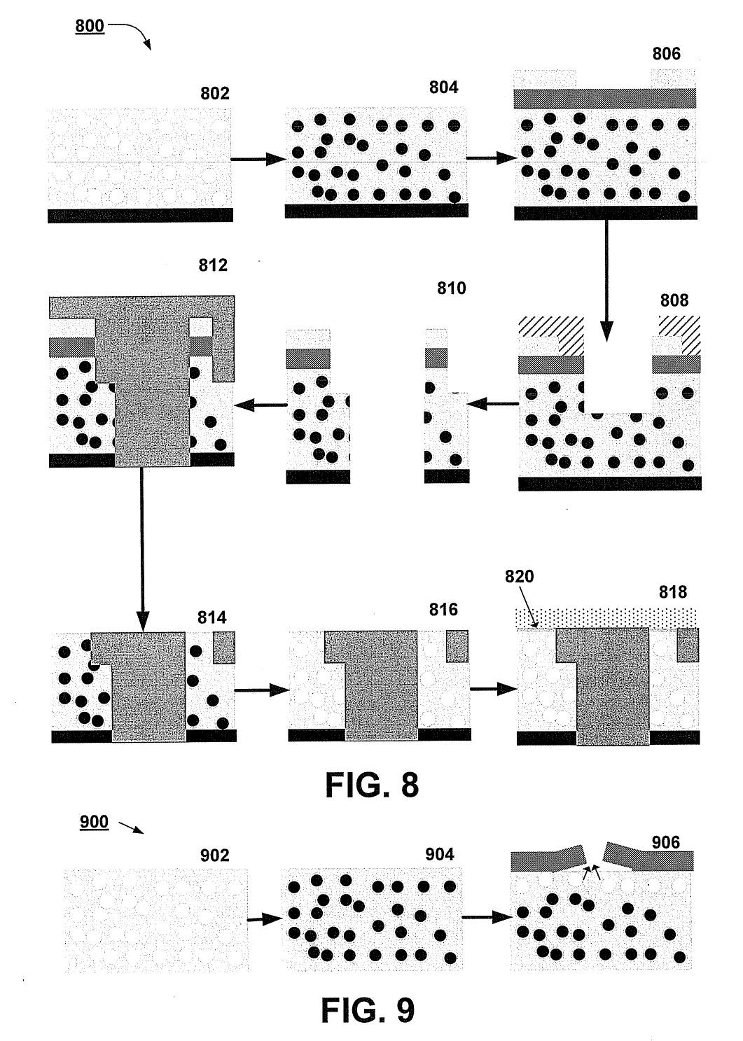

A simple pore backfilling dual damascene process 800 as illustrated in FIG. 8 can eliminate the PID damage from the conventional dual damascene process 700 of FIG. 7, but can exhibit similar surface damage 820 due to the pre-CLN with NH₃ plasma. After copper CMP, the backfilling material is removed. However, pre-CLN, which removes copper oxide on the copper, causes surface plasma damage, which is hard to remove.

In the simple pore backfilling dual damascene process 800, the porous low-k material is deposited and cured 802. A backfill material is added to the porous low-k material 804, effectively sealing the pores. Sealing the pores creates a dielectric material that is more resistant to damage during further processing stages. HM layers are deposited on the surface of the porous low-k material, including an oxide HM on the surface of the porous low-k material and a metal HM on the surface of the oxide HM, and the metal HM is opened 806. A via mask is applied and, using the via mask as a guide, a via is defined through etching through the HM layers and into the low-k dielectric material; the via mask is removed, and a trench is etched through the HM layers and the low-k dielectric 810. The via and trench are then simultaneously filled, creating a copper-filled trench and via 812. The HM layers and excess copper are removed through polishing (CMP, for example) 814, creating an interconnect. At this point, the pores of the porous low-k material are still filled with the carbon-containing backfill material. The backfill material is removed 816 from the porous low-k dielectric material. Due to the stronger carbon-containing material filling the pores of the porous low-k dielectric, the porous low-k dielectric does not exhibit the plasma damage due to the addition of copper that is evident with the conventional dual damascene process. However, when then the interconnect undergoes additional cleaning (pre-CLN with NH₃ plasma) to remove oxides from the copper and subsequent cap deposition 818, the interconnect still exhibits the surface damage 820 caused by the pre-CLN with NH₃ plasma, which can cause hygroscopicity, increased k and degraded copper reliability.

Another problem inherent with the simple pore backfilling dual damascene process is the low thermal stability of the carbon-containing backfilling material at temperatures commonly used in the dual damascene process. At temperatures above about 200 degrees C., the carbon-containing backfilling material starts to decompose. However, an oxide HM film is needed on the pore backfilled low-k film, as evidenced at element 806 of FIG. 8, to protect the dielectric material from various stages of the dual damascene process.

Currently, oxide HM films are deposited at high temperatures (over about 400 degrees C.). Under such high temperatures, the carbon-containing backfilling material is removed from the porous low-k material. This can be evidenced by the illustration 900 of FIG. 9. After the porous low-k material is deposited and cured 902 and the back fill material added to the pores 904, when the oxide hard mask is added at temperatures of 400 degrees C. or above 906, the carbon-containing backfilling material has deteriorated and become eliminated from the pores near the surface of the dielectric. This can lead to delamination of the dielectric due to release of gas from the decomposing or decomposed carbon-containing backfilling material, which causes poor adhesion between the HM and the dielectric material.

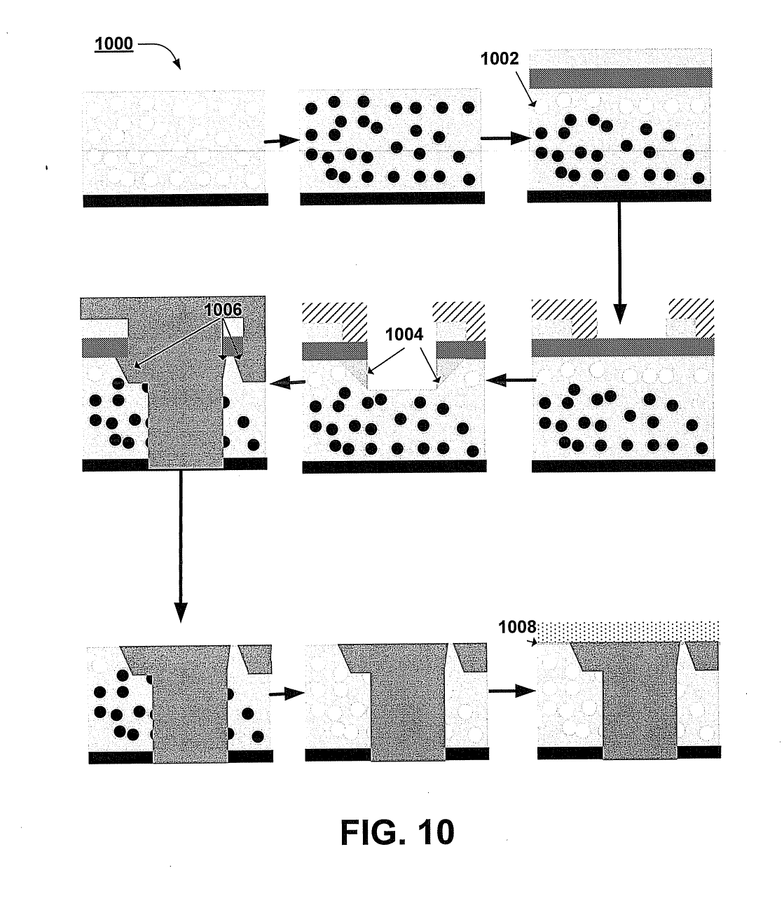

FIG. 10 illustrates a schematic diagram of a process 1000 with oxide HM deposition at a temperature of about 300 degrees C. The process is similar to the process illustrated in FIG. 8.

When the oxide hard mask deposition occurs at a high temperature (for example, about 300 degrees C.), at least a part of the carbon-containing backfilling material is removed from the porous low-k material 1002. This material can be removed in the surface region of the low-k film. The removal of the backfilling material can be due to a low thermal stability of the backfill material.

A sidewall damage layer 1004 (or bowing structure) is caused by the via etching step (and also the trench etching step, which is not shown) because of the lack of backfilling material in the surface region of the low-k film. Such a damaged layer is easily removed through post etching cleaning. The post etching cleaning can be a treatment employing a wet process (like diluted HF). This damage is bad for critical dimension (CD) control with regard to trench width. This damage also leads to void formation during copper filling.

The damage/bowing is bad for copper gap filling and trench width control. A wide trench with can negatively influence line-to-line leakage and copper reliability (TDDB) because the spacing between the copper line and adjacent copper lines is too small. A copper void can also degrade copper reliability.

The process of FIG. 10 creates a better structure than a process of FIG. 8, but the process of FIG. 10 still exhibits the surface damage 1008 caused by the pre-CLN with NH₃ plasma, which can result in hygroscopicity, an increased k and a degraded copper reliability. Pre-CLN treatment of the copper cap deposition can degrade it because Pre-CLN uses a NH₃ plasma treatment. This plasma treatment can create plasma surface damage.

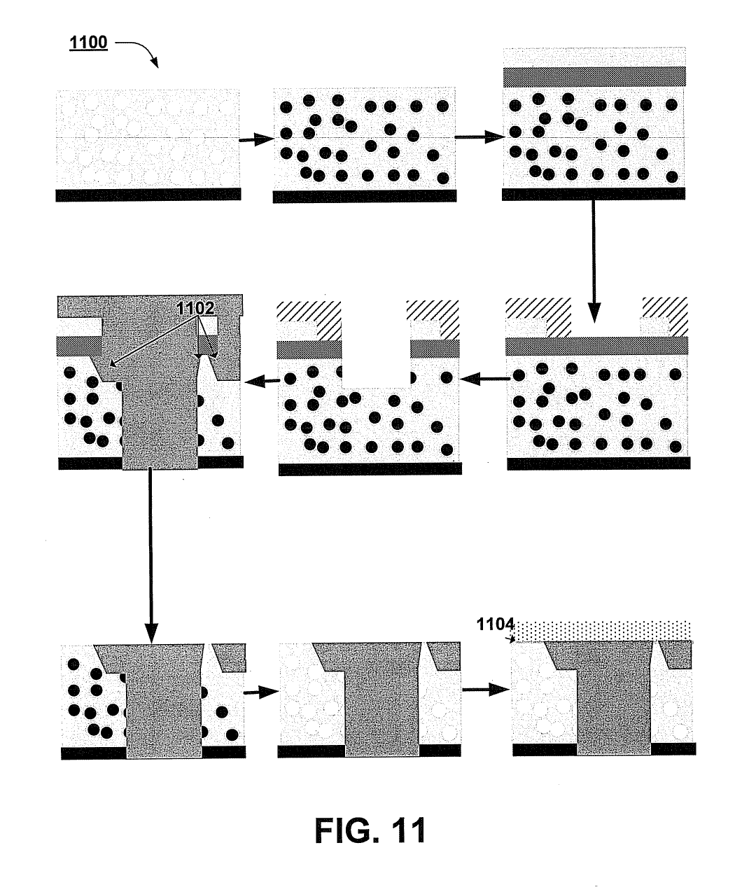

FIG. 11 illustrates a schematic diagram of a process 1100, similar to the process as illustrated in FIG. 8, with oxide HM deposition at a low temperature (e.g., less than about 200 degrees C.). If the oxide HM is deposited at a temperature less than about 200 degrees C., there is poor adhesion between the HM and the dielectric due to delamination.

Accordingly, a sidewall damage layer (not shown) occurs due to the poor RIE resistance of the HM material. When the oxide HM deposition occurs at a low temperature, the oxide HM is etched back from the sidewall surface. This can cause the sidewall etch of the low-k film.

This bowing structure is bad for copper gap filling 1002 and trench width control. The wide trench is also bad for line-to-line leakage and copper reliability (TDDB) because the spacing between the copper line and adjacent copper lines is too small.

The process of FIG. 11 creates a better structure than a process of FIG. 8, but the process of FIG. 11 still exhibits the surface damage 1104 caused by the pre-CLN with NH₃ plasma, which can result in hygroscopicity, an increased k and a degraded copper reliability. Pre-CLN treatment of cupper cap deposition degrades it. Pre-CLN uses NH₃ plasma, and this plasma treatment can create surface plasma damage.

The simple backfilling process of FIG. 8 requires a perfect backfill (FIG. 4, 404), in which all of the pores are full of carbon-containing material. Perfect fill is both difficult to achieve and difficult to remove. However, when the backfill material is added to the low-k dielectric at a different dual damascene process stage, a perfect backfill is not needed to create robust copper/porous low-k interconnects. The backfill can fill the majority of pores, but not all of the pores (shown in FIG. 4, 402). In a revised pore backfilling process, the backfill material need not be added until after the oxide HM is deposited an opened. This eliminates the problem of the thermal instability of the carbon-containing backfill material and the potential for delamination. Additionally, perfect backfilling performance is unnecessary. The carbon-containing backfilling material is only needed around the via and the trench pattern to increase the material strength for the patterning and eliminating associated plasma damage and near the surface to eliminate the surface damage due to pre-CLN. To eliminate surface damage due to pre-CLN, the backfilling material can be removed after the pre-CLN or cap deposition.

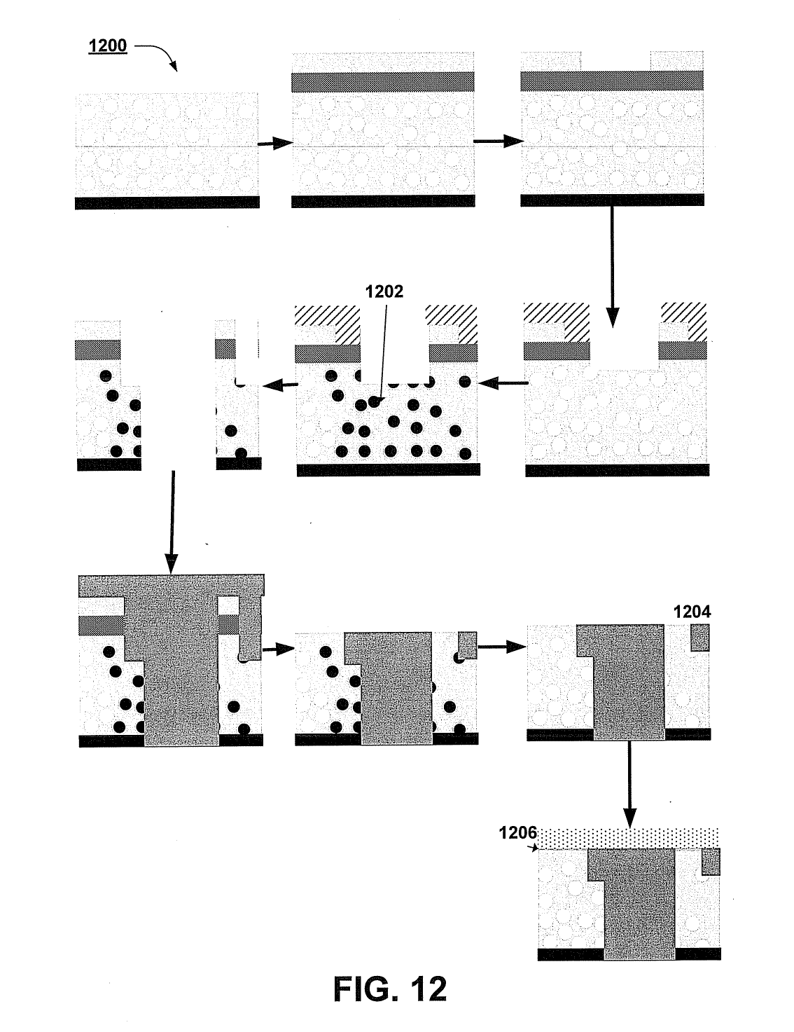

FIG. 12 is an illustration of a dual damascene process 1200 with an incomplete backfill. The backfill material 1202 need only surround the via region. Some pores far from the via region are not refilled. Accordingly, the backfill material need not be a “perfect” backfill.

In this case, the via etch is a three step process, although not all steps are illustrated. The first etch step is stopped short. During the next trench oxide hard mask etch, the via is slightly etched (second via etch). At the next trench etch step, the via etch is completed (third via etch step) simultaneously. The pore backfilling can be applied just after the via oxide mask etch and just before the first via etch.

The backfill material can be removed 1204 after the excess metal and the hard masks are removed. Since the pre-CLN and the cap addition stages still occur after the backfill is removed, the process of FIG. 12 still exhibits the surface damage 1206 caused by the pre-CLN with NH₃ plasma, which can result in hygroscopicity, an increased k and a degraded copper reliability.

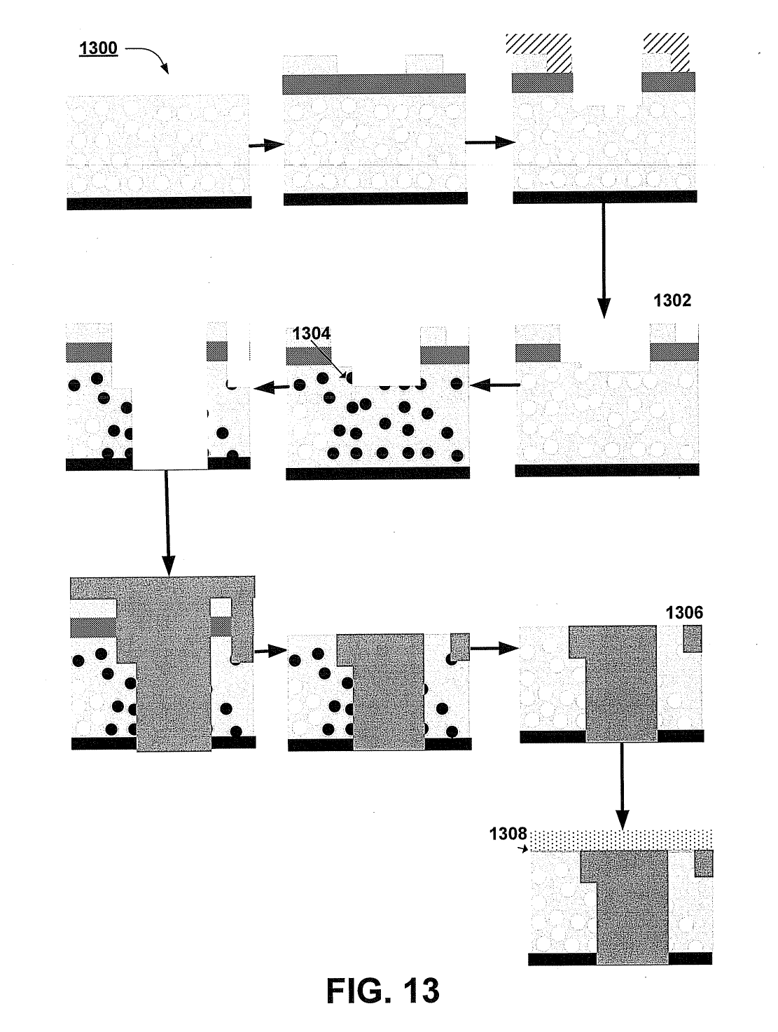

Another dual damascene process 1300 is illustrated in FIG. 13. Like the process 1200 of FIG. 12, the backfill material, which is added after the trench HM etch stage 1302, need not be a perfect backfill 1304. The backfill material can be applied around the via and the trench, while pores that are far from the trench and the via regions are not backfilled.

In this case, the via etch is a three step process, although not all steps are illustrated. The first etch step is stopped short. During the next trench oxide hard mask etch, the via is slightly etched (second via etch). At the next trench etch step, the via etch is completed (third via etch step, which contains the copper cap etch step) simultaneously. The pore backfilling can be applied just after the trench oxide mask etch step and just before the first etch step.

The backfill material can be removed after the excess metal and the hard masks are removed 1306. Since the pre-CLN and the cap addition stages still occur after the backfill is removed, the process of FIG. 13 still exhibits the surface damage 1308 caused by the pre-CLN with NH₃ plasma, which can result in hygroscopicity, an increased k and a degraded copper reliability.

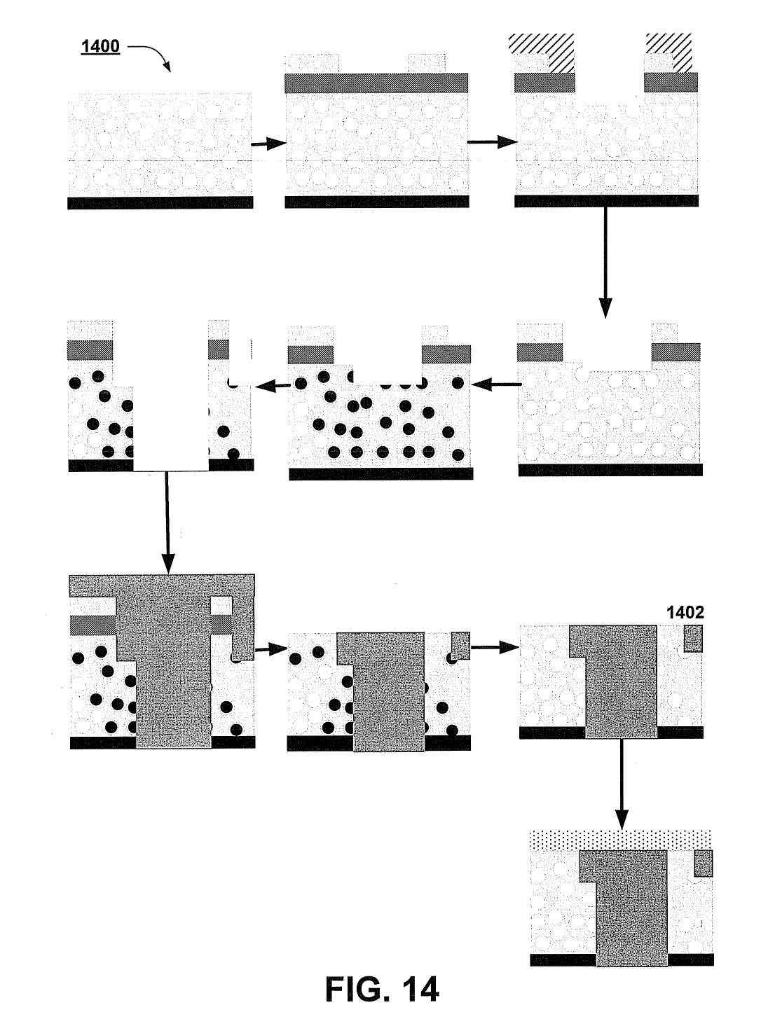

FIG. 14 illustrates a dual damascene process 1400 similar to the dual damascene process 1300 of FIG. 13. In FIG. 14, however, the backfill material is only removed 1402 after the first pre-CLN stage. The purpose of pre-CLN is to remove copper oxide from the copper top surface. At that time, plasma attacks the low-k film and generally makes a damage layer. A backfilled low-k film has a high plasma resistance for pre-CLN. Therefore, since the NH₃ pre-CLN occurs before the removal of backfill material, plasma damage from the pre-CLN can be avoided.

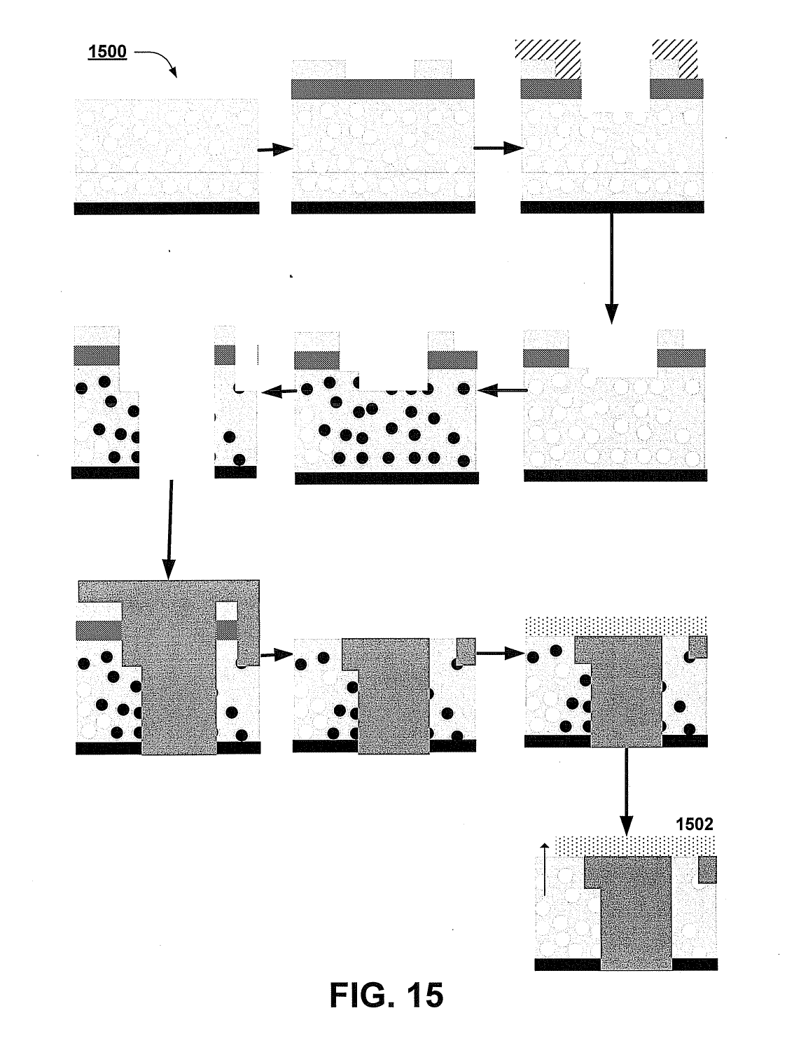

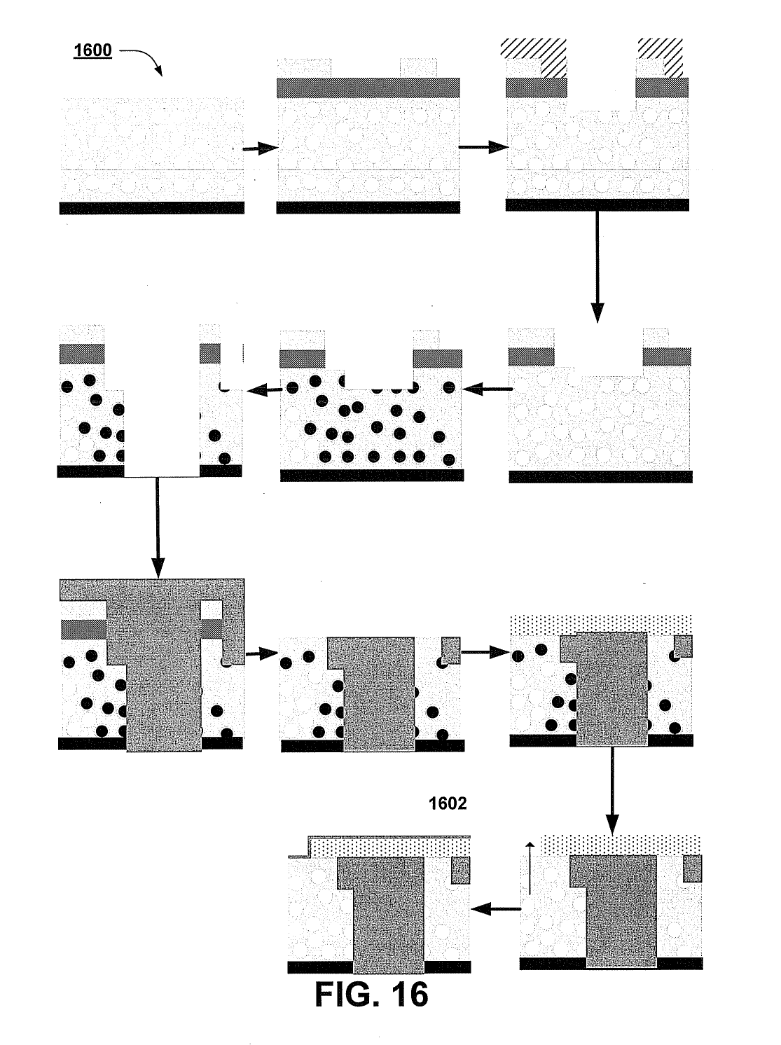

FIG. 15 illustrates a dual damascene process 1500 similar to the dual damascene process 1400 of FIG. 14. In FIG. 15, however, the backfill material is only removed 1502 after the pre-CLN and the cap is added. The backfill material can help to reduce or avoid the plasma damage from the NH₃ plasma treatment.

The pore backfilling material is removed after the copper cap deposition. To remove the backfill material, a portion of the cap is left open (through window patterning) so the backfill material can escape.

FIG. 16 illustrates a dual damascene process 1600 similar to the dual damascene process 1500 of FIG. 15. Like with regard to FIG. 15, the backfill material is removed after the pre-CLN and the cap is added. The backfill material can help to reduce or avoid the plasma damage from the NH₃ plasma treatment. The pore backfilling material is removed after the copper cap deposition. To remove the backfill material, a portion of the cap is left open (through window patterning) so the backfill material can escape. A second copper cap 1602 can be added after the backfill material removal. This second copper cap .1602 can be added to cover the portion of the first copper cap that is left open.

Other than in the operating examples, or where otherwise indicated, all numbers, values and/or expressions referring to quantities of ingredients, reaction conditions, etc., used in the specification and claims are to be understood as modified in all instances by the term “about.”

While certain embodiments have been described, these embodiments have been presented by way of example only, and are not intended to limit the scope of the inventions. Indeed, the methods and devices described herein can be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the subject innovation.

What is claimed is:

1. A method for copper/low-k dielectric material integration, comprising:
depositing a mask on a low-k dielectric material, wherein the low-k dielectric material comprises pores;
patterning a via;
backfilling a portion of the pores of the low-k dielectric material;
patterning a trench in the portion of the pores;
filling the trench and the via with copper;
removing the mask and the copper filling the via; and
removing the backfill material.

2. The method of claim 1, wherein at least a portion of the pores are connected pores.

3. The method of claim 1, wherein the backfilling further comprises leaving pores of the low-k dielectric material other than the portion of the pores unfilled.

4. The method of claim 3, wherein the backfilling is performed just before the patterning of the via and the portion of the pores is located around the via.

5. The method of claim 3, wherein the backfilling is performed just before the patterning of the trench and the portion of the pores is located just around the trench.

6. The method of claim 3, wherein the backfilling is performed just after mask patterning of the via and the portion of the pores is located around the via.

7. The method of claim 3, wherein the backfilling is performed just after mask patterning of the trench and the portion of the pores is located just around the trench.

8. The method of claim 1, wherein the backfill material comprises a resin thermally stable at temperatures less than about T_{O} and subject to thermal decomposition at temperatures greater than or equal to about T_{O}, where about 200 degrees C.<T_{O}<about 400 degrees C.

9. The method of claim 1, wherein removing the backfill material employs a thermal treatment or a wet treatment.

10. The method of claim 9, wherein removing the backfill material employs an ultra violet assist or an electron beam assist.

11. A method for copper/low-k dielectric material integration, comprising:
depositing a mask on a porous low-k dielectric material, wherein the porous low-k dielectric material comprises connecting pores;
patterning a via;
patterning a trench in the porous low-k dielectric material;
backfilling a portion of the pores around the trench with a backfill material while leaving the rest of the pores unfilled;
filling the trench and the via with copper;
removing the mask and the copper filling the via;
pre-cleaning and depositing a first cap;
patterning the first cap;
removing the backfill material; and
depositing a second cap.

12. A method for copper/low-k dielectric material integration, comprising:
depositing a mask on a low-k dielectric material, wherein the low-k dielectric material comprises pores;
patterning a via in the mask;
backfilling a portion of the low-k dielectric material with a backfill material;
patterning a trench in the low-k dielectric material, the trench being formed in at least the portion of the pores;
filling the trench and the via with copper;
removing the mask and the copper filling the via;
depositing a first cap;
patterning the first cap;
removing the backfill material; and
depositing a second cap.

13. The method of claim 12, wherein the backfilling further comprises leaving pores of the low-k dielectric material other than the portion of the pores unfilled.

14. The method of claim 13, wherein the backfilling is performed just before the patterning of the via and the portion of the pores is located just around the via.

15. The method of claim 13, wherein the backfilling is performed just before the patterning of the trench and the portion of the pores is located just around the trench.

16. The method of claim 12, wherein the low-k material dielectric material comprises silicon, carbon, oxygen and hydrogen.

17. The method of claim 12, wherein the backfill material comprises carbon and hydrogen.

18. The method of claim 12, wherein removing the backfill material employs a thermal treatment performed at a temperature less than about 450 degrees Celsius or a wet treatment.

19. The method of claim 18, wherein removing the backfill material employs an ultra violet assist or an electron beam assist.

20. The method of claim 12, wherein the mask comprises staked films.
